(19) United States
(12) Patent Application Publication
(10) Pub. No.: US 2026/0223309 A1
(43) Pub. Date: Jul. 30, 2026

(54) ELECTRONIC DEVICE

(71) Applicant: TDK Corporation, Tokyo (JP)

(72) Inventor: Yoshihiro SATO, Tokyo (JP)

(73) Assignee: TDK Corporation, Tokyo (JP)

(21) Appl. No.: 19/456,240

(22) Filed: Jan. 22, 2026

(30) Foreign Application Priority Data
Jan. 29, 2025 (JP) 2025-013205

(51) Int. Cl. H05K 5/06; H05K 5/00

(52) U.S. Cl. CPC H05K 5/062; H05K 5/0047

(57) ABSTRACT

An electronic device capable of preventing penetration of liquid from outside with simpler configuration. The electronic device includes electronic substrate, base plate wherein electronic substrate is placed, cover which is fixed to base plate, and resin portion; base plate includes bottom surface, wall portion including first and second sidewall portions, and cover contact portion including first groove portion, first and second sidewall portions extend from bottom surface in direction wherein electronic substrate is disposed; cover contact portion is between first and second sidewall portions, cover includes cover surface facing electronic substrate and plate contact portion that contacts with cover contact portion, and has second groove portion; resin portion includes at least one of first resin portion fixed to plate contact portion and first and second resin portions fixed to plate contact and second sidewall portions, and third resin portion is provided in at least one first and second groove portions.

### CROSS-REFERENCE TO RELATED APPLICATIONS

The present application claims priority under 35 U.S.C. § 119 to Japanese Patent Application No. 2025-013205 filed on Jan. 29, 2025, the entire contents of which are incorporated herein by reference.

### FIELD

The present disclosure relates to an electronic device.

### BACKGROUND

In an electronic device, in order to protect an electronic substrate on which an electronic component is mounted from liquid or the like, a waterproof structure may be provided between a case main body on which the electronic substrate is placed and a cover attached which is attached so as to cover an opening portion of the case body. For example, Patent Publication JP-A-2011-205002 discloses an electronic control device that maintains waterproofness by providing a case main body with a groove portion, bonding together the case main body and a cover with an adhesive filling the groove portion, and providing a space in a portion of a gap between the case main body and the cover which is located outside of the groove portion to confine liquid penetrating from the outside in the space by capillary action. In addition, for example, WO 2019/073910 discloses a sealing structure that can prevent liquid from penetrating into a housing for containing a vehicle-mounted electronic component by providing a sealing member formed of a gasket between an upper surface of an erecting portion of a case main body and a recessed portion provided in a cover.

### SUMMARY

However, it is considered that, in the technologies described in Patent Publication JP-A- 2011-205002 and WO 2019/073910, e.g., the cover needs to be bent, which may complicate manufacturing steps, and it is also considered that, as a result of providing the cover with a bent portion, a device size reduction may be difficult.

One aspect of the present disclosure has been achieved in view of such circumstances, and it is an object thereof to provide an electronic device capable of preventing penetration of liquid or the like from the outside with a simpler configuration.

An electronic device according to an aspect of the present disclosure includes: an electronic substrate on which an electronic component is mounted; a base plate on which the electronic substrate is placed; a cover which is fixed to the base plate; and a resin portion, wherein the base plate includes: a bottom surface; a wall portion including a first sidewall portion and a second sidewall portion; and a cover contact portion including a first groove portion, wherein the first sidewall portion and the second sidewall portion extend from the bottom surface in a direction in which the electronic substrate is disposed, wherein the cover contact portion is provided between the first sidewall portion and the second sidewall portion, and wherein the cover includes: a cover surface facing the electronic substrate; and a plate contact portion that comes into contact with the cover contact portion, and has a second groove portion provided in at least a portion thereof, and wherein the resin portion includes: at least one of a first resin portion which is fixed to the plate contact portion and to the first sidewall portion and a second resin portion which is fixed to the plate contact portion and to the second sidewall portion; and a third resin portion which is provided in at least one of the first groove portion and the second groove portion.

According to the present disclosure, it is possible to provide an electronic device capable of preventing penetration of liquid or the like from the outside with a simpler configuration.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a schematic perspective view of an electronic device according to the example embodiment;

FIG. 2A is a perspective view of a base plate according to the example embodiment;

FIG. 2B is a plan view of the base plate according to the example embodiment;

FIG. 3A is a perspective view of a cover according to the example embodiment;

FIG. 3B is a plan view of the cover according to the example embodiment;

FIG. 4 is an enlarged cross-sectional view of a portion of the electronic device according to the example embodiment;

FIG. 5A is an enlarged cross-sectional view of a portion of the electronic device according to the example embodiment;

FIG. 5B is an enlarged cross-sectional view of a portion of an electronic device according to a comparative example;

FIG. 6A is a photograph of a portion of the electronic device according to the comparative example;

FIG. 6B is a photograph of a portion of the electronic device according to the example embodiment;

FIG. 7A is an enlarged cross-sectional view of a portion of the electronic device according to the example embodiment;

FIG. 7B is an enlarged cross-sectional view of a portion of the electronic device according to the example embodiment;

FIG. 7C is an enlarged cross-sectional view of a portion of the electronic device according to the example embodiment;

FIG. 8 is an enlarged cross-sectional view of a portion of the electronic device according to the example embodiment;

FIG. 9A is a schematic cross-sectional view for illustrating a method of forming a first groove portion according to the example embodiment;

FIG. 9B is a schematic cross-sectional view for illustrating the method of forming the first groove portion according to the example embodiment;

FIG. 9C is a schematic cross-sectional view for illustrating the method of forming the first groove portion according to the example embodiment;

FIG. 10A is a perspective view of the base plate according to the example embodiment;

FIG. 10B is a plan view of the base plate according to the example embodiment;

FIG. 11A is a perspective view of a second cover according to the example embodiment;

FIG. 11B is a plan view of the second cover according to the example embodiment;

FIG. 12 is an enlarged cross-sectional view of a portion of the electronic device according to the example embodiment;

FIG. 13 is a schematic exploded perspective view of the electronic device according to the example embodiment; and

FIG. 14 is a schematic exploded perspective view of the electronic device according to the example embodiment.

### DETAILED DESCRIPTION

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

Referring to the accompanying drawings, a description will be given below of one example embodiment (hereinafter referred to also as the “example embodiment”) of the present disclosure. Note that, in the drawings accompanying the present specification, for the convenience of ease of illustration and understanding, a scale, an aspect ratio, and the like may appropriately be changed and exaggerated from those of an actual substance.

In the following, an X-axis, a Y-axis, and a Z-axis may be shown in each of drawings. The X-axis, the Y-axis, and the Z-axis form right-handed three-dimensional orthogonal coordinates. Hereinbelow, an arrow direction of the X-axis may be referred to as a +X-axis direction, while a direction opposite to the arrow direction may be referred to as a −X-axis direction. The same applies also to the other axes. Note that, a +Z-direction and a −Z-direction may be referred to as an “upper side” or “upside” and a “lower side” or “underside”, respectively. A Z-axis direction may be referred to also as the “stacking direction”. Furthermore, planes orthogonal to the X-axis, the Y-axis, and the Z-axis may be referred to also as a YZ-plane, a ZX-plane, and an XY-plane, respectively. Note that these directions and the like are used for the sake of convenience to describe relative positional relationships. Therefore, these directions and the like are not intended to define absolute positional relationships.

In the following, terms and/or numerical values that mean shapes and/or geometric conditions are not necessarily limited to strict definitions thereof, and may also be construed to include a range to a degree that similar functions may be expected. For example, terms such as “parallel” and/or “orthogonal” correspond to the terms mentioned above. Meanwhile, values such as “values of length” and/or “values of angle” or the like correspond to the numerical values mentioned above.

In a case where a given component is expressed as being “on”, “under”, “on an upper side of”, “on a lower side of”, “above”, or “below” another component, the case may also include an aspect in which the given component is in direct contact with the other component and an aspect in which a different component is included between the given component and the other component. In other words, the aspect in which the different component is included between the given component and the other component may also be expressed as the given component and the other component being in indirect contact with each other. The expression “on”, “upper side”, or “above” is replaceable with the expression “under”, “lower side”, or “below”. In other words, an up-down direction may also be reversed. The same applies also to a left-right direction.

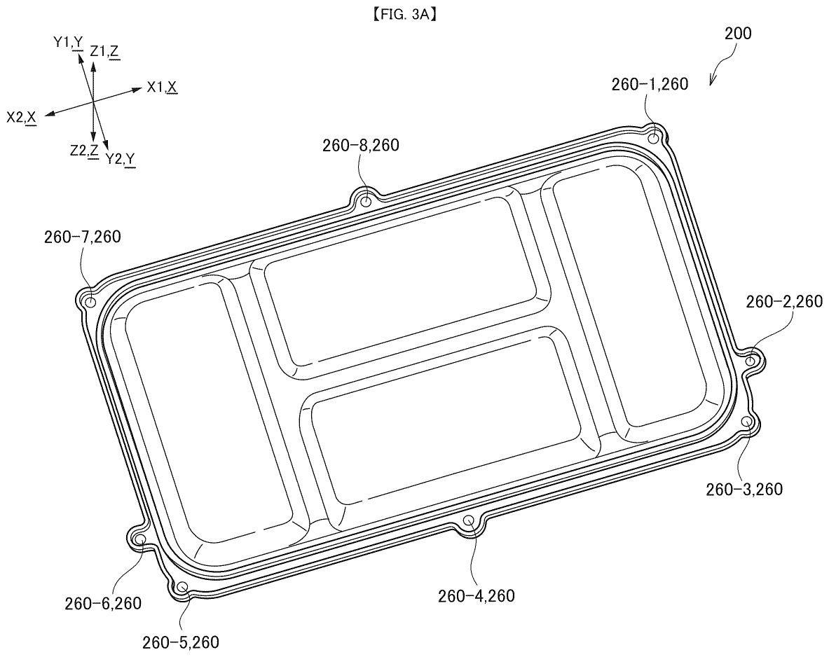

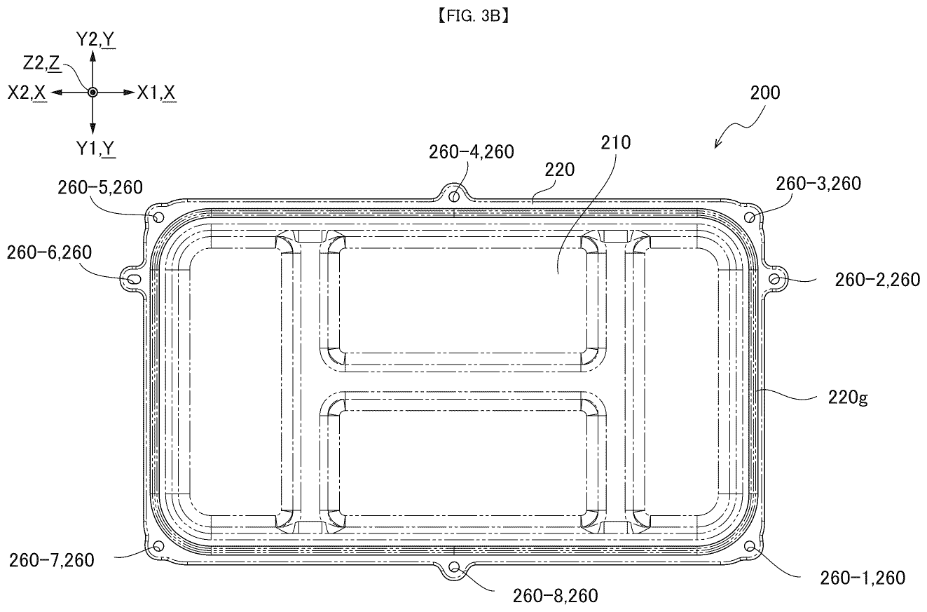

In addition, to describe a relative directional relationship, for the sake of convenience, a rightward direction on the sheet surface in FIG. 3B described later may be referred to as a right side X1, a leftward direction opposite thereto on the sheet surface may be referred to as a left side X2, and the both directions may be generically referred to as a lateral direction X. Moreover, an upward direction on the sheet surface in FIG. 3B may be referred to as a front side Y1, a downward direction opposite thereto on the sheet surface may be referred to as a rear side Y2, and the both directions may be generically referred to as a front-rear direction Y. Further, a depth direction orthogonal to the sheet surface in the same drawing may be referred to as a lower side Z2, a forward direction opposite thereto and orthogonal to the surface sheet may be referred to as an upper side Z1, and the both directions may be generically referred to as a vertical direction Z. Furthermore, a top view (bottom view) refers to a viewpoint when an electronic device 10 or the like is viewed from a position on the upper side Z1 (the lower side Z2), while facing the lower side Z2 (the upper side Z1).

In the following, when identical portions and/or portions having similar functions are designated by identical reference signs or like reference signs, a repeated description may be omitted. The ratio of dimensions in the drawings may differ from an actual ratio. Illustration of some of components in an example embodiment may be omitted from the drawings.

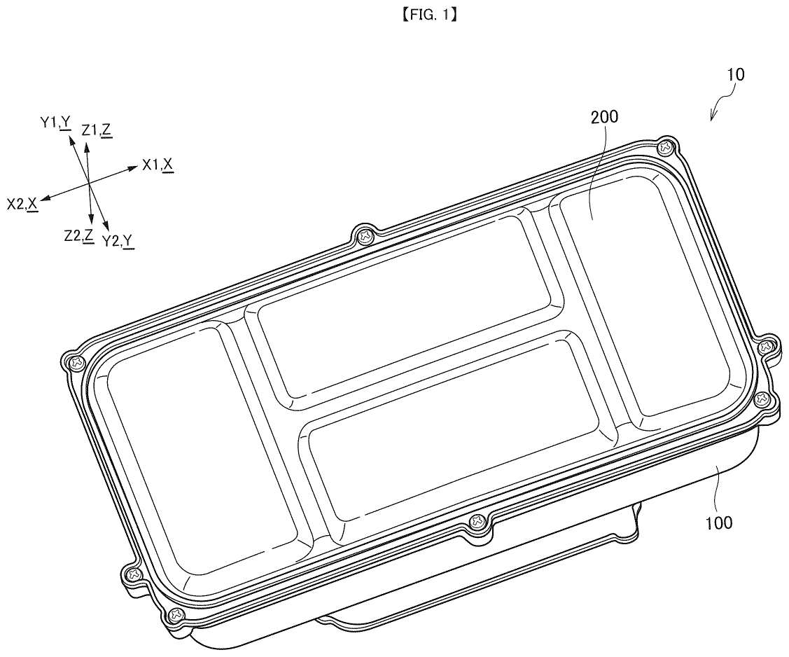

FIG. 1 is a schematic perspective view of the appearance of the electronic device 10 according to the present example embodiment. As shown in FIG. 1, the electronic device 10 according to the example embodiment includes a base plate 100 on which an electronic substrate and the like are disposed and which is open to one side (upper side), and a cover 200 disposed above the base plate 100.

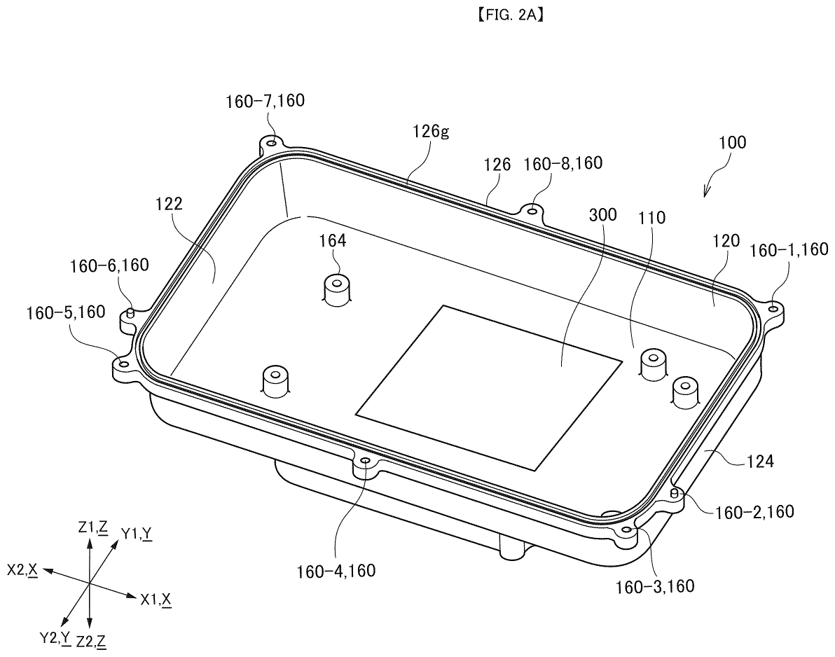

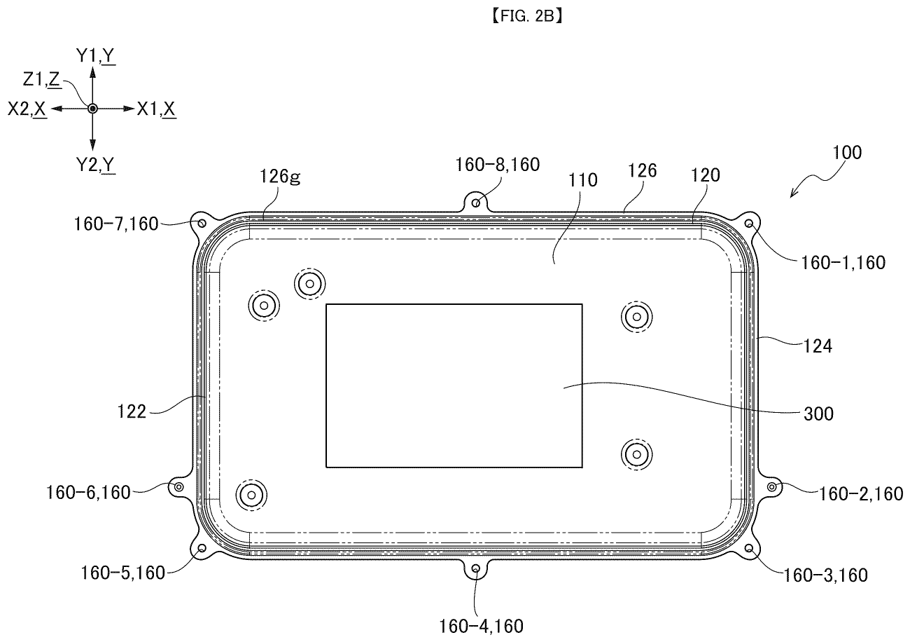

Referring to FIG. 2A and FIG. 2B, the base plate 100 of an electronic device 10 according to the example embodiment will be described. FIG. 2A is a perspective view of the base plate 100 as viewed from above. FIG. 2B is a plan view of the base plate 100 as viewed from above.

As shown in FIG. 2A and FIG. 2B, the base plate 100 has a bottom surface 110 and a wall portion 120. On the bottom surface 110, an electronic substrate 300 on which an electronic component is mounted is placed.

The wall portion 120 has a first sidewall portion 122, a second sidewall portion 124 disposed outside of the first sidewall portion 122, and a cover contact portion 126. The cover contact portion 126 may also be provided between the first sidewall portion 122 and the second sidewall portion 124.

As shown in FIG. 2A and FIG. 2B, the first sidewall portion 122 may also be an inner surface of the wall portion 120, and the second sidewall portion 124 may also be an outer surface of the wall portion 120. The cover contact portion 126 is provided with a first groove portion 126g. The cover contact portion 126 may also be a plane located above the wall portion 120, and may also be, e.g., a plane perpendicular to the vertical direction. The first groove portion 126g may also be formed so as to be recessed downward in the wall portion 120. The first groove portion 126g may also be provided, e.g., along the entire circumference of the wall portion 120.

In the example embodiment, the wall portion 120 of the base plate 100 may also be provided, e.g., along the entire circumference of the electronic substrate placement surface 110. As shown in FIG. 2A and FIG. 2B, the base plate 100 may also be provided with, e.g., a cover fixing portion 160 that fixes a cover 200 described later to the base plate 100. A plurality of the cover fixing portions 160 may also be provided. In addition, the cover fixing portion 160 may also include, e.g., a screw hole into which a screw can be inserted. The base plate 100 may also be provided with one or a plurality of fixing portions 164 to which another element other than the electronic substrate 300, a power supply device, and the like are to be fixed.

Referring to FIG. 3A and FIG. 3B, the cover 200 of the electronic device 10 according to the example embodiment will be described. FIG. 3A is a perspective view of the cover 200 as viewed from above. FIG. 3B is a plan view of the cover 200 as viewed from below.

As shown in FIG. 3B, the cover 200 has a cover surface 210 facing the electronic substrate 300 (FIG. 2A and FIG. 2B). Note that, in the electronic device 10 according to the example embodiment, as shown in FIG. 1, the cover 200 is provided above the base plate 100 and, in a state where the cover 200 is fixed to the base plate 100, the cover surface 210 of the cover 200 is located at a position facing the electronic substrate 300 placed on the base plate 100.

As shown in FIG. 3B, the cover 200 has a plate contact portion 220 with which the cover contact portion 126 comes into contact. The plate contact portion 220 is provided around the cover surface 210. In the electronic device 10 according to the example embodiment, the cover contact portion 126 of the base plate 100 and the plate contact portion 220 of the cover 200 may also have the same shape when viewed in plan view. Accordingly, in the example embodiment, when the cover 200 is fixed to the base plate 100, the cover contact portion 126 of the base plate 100 and the plate contact portion 220 of the cover 200 may also be configured so as to overlap each other in a Z-direction.

At least a portion of the plate contact portion 220 is provided with a second groove portion 220g. In the example embodiment, the second groove portion 220g is provided, e.g., along the entire circumference of the plate contact portion 220. The second groove portion 220g is formed so as to be recessed upward from the plate contact portion 220 in a state where the cover 200 is fixed to the base plate 100.

As shown in FIG. 3B, the plate contact portion 220 of the cover 200 may also be provided along the entire circumference of the cover surface 210. As shown in FIG. 3A and FIG. 3B, the cover 200 may also be provided with, e.g., a plate fixing portion 260 that fixes the cover 200 to the base plate 100. A plurality of the plate fixing portions 260 may also be provided. In addition, the plate fixing portion 260 may also include, e.g., a screw hole into which a screw can be inserted.

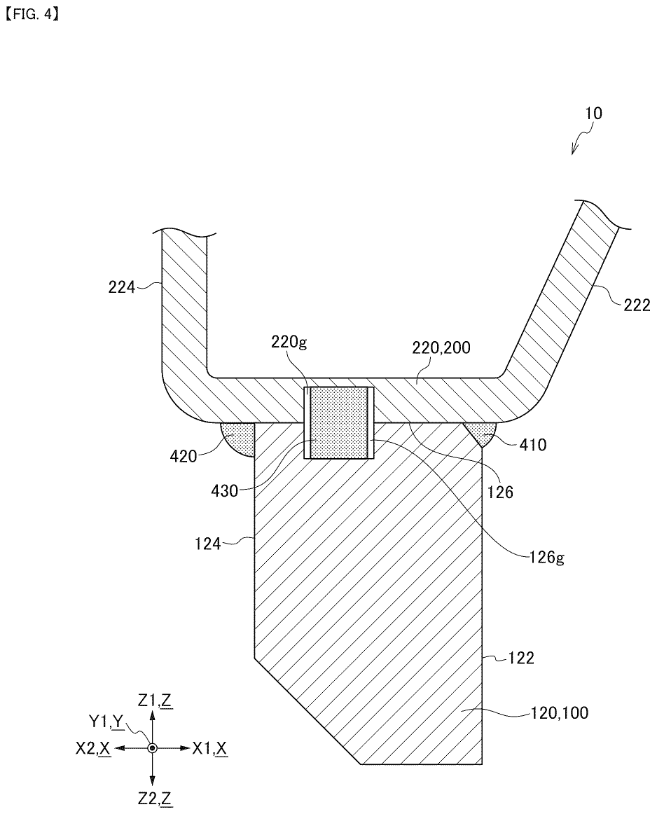

FIG. 4 illustrates an enlarged cross-sectional view of respective portions of the base plate 100 and the cover 200 of the electronic device 10 which are in contact with each other as viewed from a-Y-direction. The electronic device 10 according to the example embodiment is provided with at least one of a first resin portion 410 which is fixed to the plate contact portion 220 of the cover 200 and to the first sidewall portion 122 of the base plate 100 and a second resin portion 420 which is fixed to the plate contact portion 220 of the cover 200 and to the second sidewall portion 124 of the base plate 100. In the example shown in FIG. 4, each of the first resin portion 410 and the second resin portion 420 is provided. Note that, in the electronic device 10 according to the example embodiment, each of the first resin portion 410 and the second resin portion 420 may also be provided as a gasket that seals a gap between the cover contact portion 126 of the base plate 100 and the plate contact portion 220 of the cover 200, which is a joint portion between the base plate 100 and the cover 200.

For example, the second resin portion 420 is provided so as to prevent moisture or the like from penetrating from the outside (e.g., the left side X2) of the electronic device 10 into the interior of the electronic device 10. Meanwhile, the first resin portion 410 is provided so as to prevent moisture, which has penetrated from the outside (e.g., the left side X2) of the electronic device 10 and may penetrate to the inner side (the right side X1) along the joint portion between the base plate 100 and the cover 200 (between the cover contact portion 126 of the base plate 100 and the plate contact portion 220 of the cover 200), from penetrating into the interior of the electronic device 10.

In addition, the electronic device 10 according to the example embodiment has a third resin portion 430 provided in at least one of the first groove portion 126g and the second groove portion 220g. In the example shown in FIG. 4, e.g., the first groove portion 126g is provided so as to have a rectangular shape when viewed in cross-sectional view. Meanwhile, the second groove portion 220g is provided so as to have a rectangular shape when viewed in cross-sectional view. Moreover, the third resin portion 430 is provided to extend between the first groove portion 126g and the second groove portion 220g.

Note that, as shown in FIG. 4, in the vicinity of the plate contact portion 220, the cover 200 may also have, e.g., an inner wall portion 222 provided so as to extend diagonally upward (to the right side X1 and the upper side Z1) on the right side X1 (inner side) in FIG. 4 and an outer wall portion 224 provided so as to extend to the upper side Z1 on the left side X2 (outer side) in FIG. 4. The inner wall portion 222 may also be connected to, e.g., the cover surface 210.

As has been described above, the electronic device 10 according to the example embodiment in an aspect of the present disclosure includes the electronic substrate 300 on which the electronic component is mounted, the base plate 100 on which the electronic substrate 300 is placed, the cover 200 which is fixed to the base plate 100, and the resin portion 400. The base plate 100 has the bottom surface 110, the wall portion 120, and the cover contact portion 126. The wall portion 120 includes the first sidewall portion 122 and the second sidewall portions 124. The cover contact portion 126 includes the first groove portion 126g. The first sidewall portion 122 and the second sidewall portion 124 extend from the bottom surface 110 in the direction (Z-Direction) in which the electronic substrate 300 is disposed. The cover contact portion 126 is provided between the first sidewall portion 122 and the second sidewall portion 124. The cover 200 has the cover surface 210 facing the electronic substrate 300, and the plate contact portion 220 that comes into contact with the cover contact portion 126, and has the second groove portion 220g provided in at least a portion thereof. The resin portion 400 includes at least one of the first resin portion 410 which is fixed to the plate contact portion 220 and to the first sidewall portion 122 and the second resin portion 420 which is fixed to the plate contact portion 220 and to the second sidewall portion 124, and the third resin portion 430 provided in at least one of the first groove portion 126g and the second groove portion 220g. In the electronic device 10 according to the example embodiment in the aspect of the present disclosure, with the configuration described above, it is possible to delay corrosion of the base plate 100, the cover 200, and the like due to penetration of liquid or the like from the outside of the electronic device 10, and consequently it is possible to prevent the liquid or the like from penetrating into the interior of the electronic device 10.

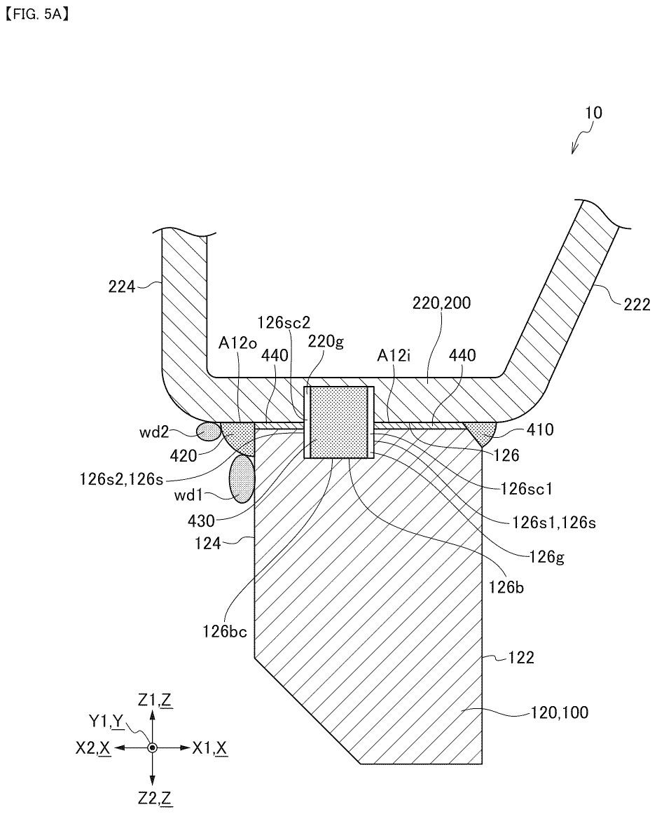

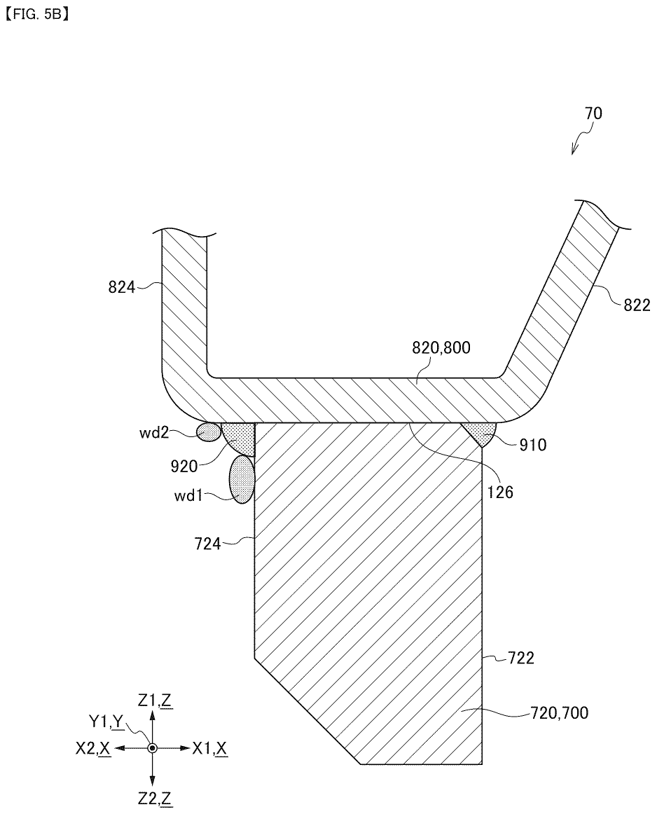

Referring to FIG. 5A and FIG. 5B, a description will be given of the foregoing function effect of the electronic device 10 according to the example embodiment in the aspect of the present disclosure by using a comparative example. FIG. 5A is an enlarged cross-sectional view of the respective portions of the base plate 100 and the cover 200, which are in contact with each other, in the electronic device 10 according to the example embodiment as viewed from the −Y-direction. FIG. 5B illustrates an enlarged cross-sectional view of respective portions of a base plate 700 and a cover 800, which are in contact with each other, in an electronic device 70 in the comparative example as viewed from the −Y-direction.

As shown in FIG. 5B, the base plate 700 in the electronic device 70 according to the comparative example is provided with a first sidewall portion 722 and a second sidewall portion 724, similarly to the base plate 100 in the electronic device 10 according to the example embodiment. Meanwhile, the base plate 700 in the electronic device 70 according to the comparative example is different from the base plate 100 in the electronic device 10 according to the example embodiment in that a cover contact portion 726 of the base plate 700 is not provided with the first groove portion 126g of the base plate 100 in the electronic device 10 according to the example embodiment. The cover 800 of the electronic device 70 according to the comparative example is provided with a plate contact portion 820, and is also provided with an inner wall portion 822 and an outer wall portion 824, but the cover 800 of the electronic device 70 according to the comparative example is different from the electronic device 10 according to the example embodiment in that the second groove portion 220g of the cover 200 in the electronic device 10 according to the example embodiment is not provided.

In addition, as shown in FIG. 5B, the electronic device 70 according to the comparative example is provided with a first resin portion 910 which is fixed to the plate contact portion 820 of the cover 800 and to the first sidewall portion 722 of the base plate 700 and with a second resin portion 920 which is fixed to the plate contact portion 820 of the cover 800 and to the second sidewall portion 724 of the base plate 700. However, in the electronic device 870 according to the comparative example, the first groove portion 126g and the second groove portion 220g in the electronic device 10 according to the example embodiment are not provided, and therefore the same resin portion as the third resin portion 430 is not provided.

FIG. 5B also schematically illustrates a water droplet wd1 and a water droplet wd2 which adhere from the outside of the electronic device 70 according to the comparative example. As shown by the water droplet wd1 in FIG. 5B, the water droplet wd1 and the water droplet wd2 that adhere from the outside (e.g., the left side X2) of the electronic device 70 according to the comparative example adhere to, e.g., the outer side (left side X2) of the first sidewall portion 722 of the wall portion 720 of the base plate 700, the lower side of the plate contact portion 820, or the like.

In the same manner as in the first resin portion 410 and the second resin portion 420 in the electronic device 10, in the electronic device 70 according to the comparative example also, each of the first resin portion 910 and the second resin portion 920 can function as a gasket between the base plate 700 and the cover 800. Therefore, it is considered that the water droplet wd1 and the water droplet wd2 can be prevented from penetrating to the inner side (right side X1 in FIG. 5B) inside of the electronic device 70. However, according to the study conducted by the present inventors, there were cases where, even though the second resin portion 920 was provided, the water droplet wd1 and the water droplet wd2 penetrated between the cover contact portion 726 and the plate contact portion 820.

It was also found that the moisture having penetrated between the cover contact portion 726 and the plate contact portion 820 might stay, e.g., between the cover contact portion 726 and the plate contact portion 820 and corrode the cover contact portion 726 and/or the plate contact portion 820 formed of a metal material or the like. There were also cases where the water droplet wd1 and the water droplet wd2 penetrated between the gasket (second resin portion 920) and the second sidewall portion 724 and the plate contact portion 820, passed between the cover contact portion 726 and the plate contact portion 820 due to capillarity action or the like, and penetrated into the interior of the electronic device 70. Even though the first resin portion 910 was provided as the gasket on the inner side (right side X1) between the cover contact portion 726 and the plate contact portion 820, when the first resin portion 910 was insufficiently fixed to the base plate 700 or the cover 800, the function of the gasket might be insufficient and, in this case also, moisture from the outside of the electronic device 70 penetrated into the interior of the electronic device 70. It is considered that, in the electronic device 70 into which moisture has penetrated, a problem such as a short circuit may occur.

In the electronic device 10 according to the example embodiment, as described above, the cover contact portion 126 of the base plate 100 is provided with the first groove portion 126g. In addition, in the electronic device 10 according to the example embodiment, the plate contact portion 220 of the cover 200 is provided with the second groove portion 220g. Accordingly, as shown in FIG. 5A, in the electronic device 10 according to the example embodiment, even when, e.g., the water droplet wd1 and the water droplet wd2 from the outside (left side X2 in FIG. 5A) of the electronic device 10 adhere to the electronic device 10, and the water droplet wd1 and the water droplet wd2 penetrate between the cover contact portion 126 of the base plate 100 and the plate contact portion 220 of the cover 200, due to the provision of the first groove portion 126g, it is possible to set a creeping distance from the outside of the electronic device 10 to the inside thereof longer than that in the electronic device 70 according to the comparative example. Therefore, it is possible to delay or prevent penetration of the water droplet wd1 and the water droplet wd2, which have penetrated between the cover contact portion 126 of the base plate 100 and the plate contact portion 220 of the cover 200, into the interior of the electronic device 10.

Moreover, even when the water droplet wd1 and the water droplet wd2 having penetrated between the cover contact portion 126 of the base plate 100 and the plate contact portion 220 of the cover 200 move, e.g., in the direction of the cover 200 on the upper side Z1 and penetrate into the groove portion 220g, in the same manner as with the first groove portion 126g, it is possible to set the creeping distance from the outside of the electronic device 10 to the inside thereof relatively long. Therefore, it is possible to delay or prevent such penetration of the water droplet wd1 and the water droplet wd2 into the interior of the electronic device 10.

Furthermore, in the electronic device 10 according to the example embodiment, the moisture having penetrated into the first groove portion 126g provided so as to be recessed to the lower side Z2 cannot resist, e.g., the gravity, and is allowed to remain at a bottom portion 126b of the first groove portion 126g. In view of this also, it is possible to prevent the water droplet wd1 and the water droplet wd2, which have penetrated between the cover contact portion 126 of the base plate 100 and the plate contact portion 220 of the cover 200, from penetrating into the interior of the electronic device 10.

In addition, in the electronic device 10 according to the example embodiment, the third resin portion 430 is provided in at least one of the first groove portion 126g and the second groove portion 220g, and the third resin portion 430 serves as the gasket to be able to prevent moisture, which may penetrate into the first groove portion 126g and the second groove portion 220g, from penetrating into the interior of the electronic device 10.

As a result of the study conducted by the present inventors by using the electronic device 10 having the same configuration as that of the electronic device 10 according to the example embodiment, when the first groove portion 126g and the second groove portion 220g were provided, and the third resin portion 430 was provided in at least one of the first groove portion 126g and the second groove portion 220g, corrosion occurred between the base plate 100 and the cover 200 (between the cover contact portion 126 of the base plate 100 and the plate contact portion 220 of the cover 200), which were formed by using a metal material or the like, occurred in portions up to the first groove portion 126g and the second groove portion 220g, but no corrosion occurred in the portions inside of the first groove portion 126g and the second groove portion 220g.

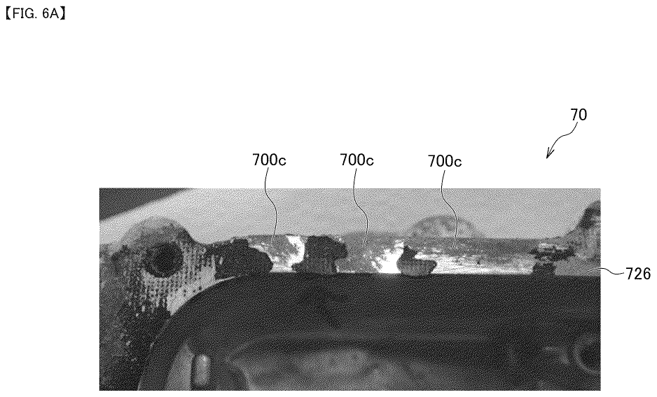

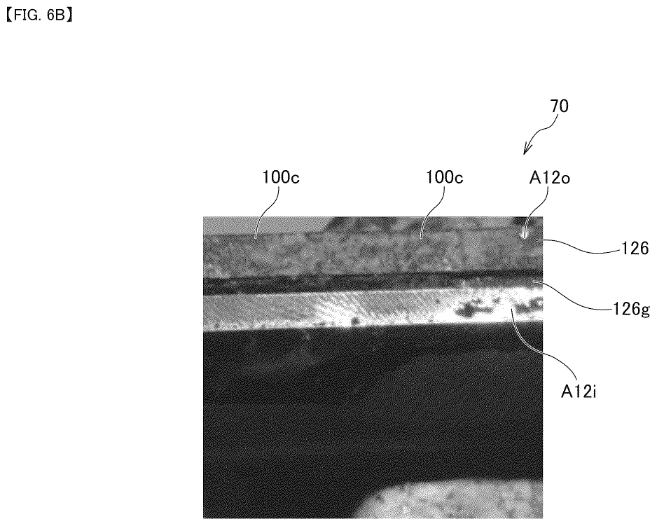

FIG. 6A shows a photograph of a portion of the cover contact portion 726 in the electronic device 70 according to the comparative example, in which the cover has been removed after a corrosion test. FIG. 6B shows a photograph of a portion of the cover contact portion 126 in the electronic device 10 according to the example embodiment, in which the cover has been removed after a corrosion test. As shown in FIG. 6A, in the electronic device 70 according to the comparative example, corroded portions 700c indicated by dark gray were observed in some portions of the cover contact portion 726. In the electronic device 10 according to the example embodiment, as shown in FIG. 6B, corroded portions 100c indicated by dark gray were observed in a region A12o of the cover contact portion 126, which is outside of the portion thereof provided with the first groove portion 126g but, in a region A12i inside of the portion provided with the first groove portion 126g, no corroded portion was found. This is conceivably because, in the electronic device 10 according to the example embodiment, the first groove portion 126g is provided as described above, and therefore the occurrence of corrosion could be prevented in the region A12i of the cover contact portion 126. In other words, it was confirmed that, in the electronic device 10 according to the example embodiment, penetration of liquid from the outside could be prevented.

While the description has been given by way of example of the case where, in the electronic device 10 according to the example embodiment that has been described with reference to FIG. 5A and the like, e.g., the first resin portion 410 and second resin portion 420 are provided, the configuration of the electronic device 10 according to the example embodiment is not limited thereto. As described above, for example, the first resin portion 410 functions as the gasket that prevents moisture, which has penetrated between the cover contact portion 126 of the base plate 100 and the plate contact portion 220 of the cover 200, from penetrating into the interior of the electronic device 10. Meanwhile, for example, the second resin portion 420 functions as the gasket that prevents the water droplet wd1 and the water droplet wd2 adhering to the electronic device 10 from the outside of the electronic device 10 from penetrating between the cover contact portion 126 of the base plate 100 and the plate contact portion 220 of the cover 200. Therefore, in the electronic device 10 according to the example embodiment, e.g., either of the first resin portion 410 and the second resin portion 420 may also be provided. In the electronic device 10 according to the example embodiment, even when, e.g., either of the first resin portion 410 and the second resin portion 420 is provided, the electronic device 10 is provided with the first groove portion 126g and the second groove portion 220g, the third resin portion 430 is provided in at least one of the first groove portion 126g and the second groove portion 220g, and therefore it is possible to effectively prevent the penetration of moisture into the interior of the electronic device 10.

Moreover, in the electronic device 10 according to the example embodiment described with reference to FIG. 5A and the like, the description has been given by way of example of the case where, e.g., the third resin portion 430 is provided in each of the first groove portion 126g and the second groove portion 220g, but the configuration of the electronic device 10 according to the example embodiment is not limited thereto. For example, the third resin portion 430 can function as a gasket, as described above, in the space formed by the first groove portion 126g and the second groove portion 220g. Accordingly, the third resin portion 430 may also be provided in either of the first groove portion 126g and the second groove portion 220g and, even in the case where the third resin portion 430 is provided in either of the first groove portion 126g and the second groove portion 220g, it is possible to effectively prevent moisture, which has penetrated between the cover contact portion 126 of the base plate 100 and the plate contact portion 220 of the cover 200, from penetrating into the interior of the electronic device 10.

As described above, in the electronic device 10 according to the example embodiment, the cover contact portion 126 of the base plate 100 is provided with the first groove portion 126g, and the plate contact portion 220 of the cover 200 is provided with the second groove portion 220g. In addition, at least one of the first resin portion 410 which is fixed to the plate contact portion 220 of the cover 200 and to the first sidewall portion 122 of the base plate 100 and the second resin portion 420 which is fixed to the plate contact portion 220 of the cover 200 and to the second sidewall portion 124 of the base plate 100 is provided. Moreover, in at least one of the first groove portion 126g and the second groove portion 220g, the third resin portion 430 is provided. Therefore, in the electronic device 10 according to the example embodiment, with a simpler configuration, it is possible to effectively prevent penetration of moisture from the outside of the electronic device 10 into the interior of the electronic device 10 due to the water droplet wd1 and the water droplet wd2.

In the electronic device 10 according to the example embodiment, either of the first resin portion 410 and the second resin portion 420 may be provided as described above but, for example, both of the first resin portion and the second resin portion 420 may also be provided. By providing the second resin portion 420 in addition to the first resin portion, it is possible to effectively prevent penetration of moisture between the cover contact portion 126 of the base plate 100 and the plate contact portion 220 of the cover 200. Therefore, it is possible to prevent the occurrence of corrosion or the like of the metal material used to form the base plate 100 and the cover 200, which may occur between the cover contact portion 126 of the base plate 100 and the plate contact portion 220 of the cover 200.

In addition, between the cover contact portion 126 of the base plate 100 and the plate contact portion 220 of the cover 200, another resin portion (fourth resin portion 440) may also be provided. For example, as shown in FIG. 5A, between the cover contact portion 126 of the base plate 100 and the plate contact portion 220 of the cover 200, in at least a portion of at least one of the region (region A12i shown in FIG. 5A) on the inner side (right side X1) of the portion provided with the first groove portion 126g and the second groove portion 220g and the region (region A12o shown in FIG. 5A) on the outer side (left side X2) of the portion provided with the first groove portion 126g and the second groove portion 220g, the fourth resin portion 440 may also be provided.

In the electronic device 10 according to the example embodiment, by providing the fourth resin portion 440, it is possible to, e.g., more effectively prevent the penetration of moisture between the cover contact portion 126 of the base plate 100 and the plate contact portion 220 of the cover 200. Note that, in FIG. 5A, the case is shown in which the fourth resin portion 440 is provided in each of the region A12i in the inner side (right X1) of the portion provided with the first groove portion 126g and the second groove portion 220g and the region A12o on the outer side (left side X2) of the portion provided with the first groove portion 126g and the second groove portion 220g, but the configuration of the electronic device 10 according to the example embodiment is not limited thereto. The fourth resin portion 440 may also be provided in only one of the region A12i and the region A12o and, even in the case where the fourth resin portion 440 is provided in only one of the region A12i and the region A12o, it is possible to effectively prevent the penetration of moisture into the interior of the electronic device 10. Alternatively, the fourth resin portion 440 may be provided in the entirety of at least one of the region A12i and the region A12o, or may also be provided only in at least a portion of at least one of the region A12i and the region A12o. In either case, it is possible to effectively prevent the penetration of moisture into the interior of the electronic device 10.

Alternatively, the electronic device 10 according to the example embodiment may also be configured such that, e.g., the first groove portion 126g of the base plate 100 and the second groove portion 220g of the cover 200 are at least partially in communication with each other. In other words, as shown in, e.g., FIG. 5A or the like, in the electronic device 10 according to the example embodiment, the first groove portion 126g and the second groove portion 220g may also be provided at positions overlapping each other in the vertical direction (Z-direction) when viewed in cross-sectional view (cross-sectional view as viewed from, e.g., the −Y-direction shown in FIG. 5A). In other words, in FIG. 5A, the first groove portion 126g and the second groove portion 220g may also be provided such that an end portion of the first groove portion 126g on the right side X1 and an end portion of the second groove portion 220g on the right side X1 are located at the same position in the Z-direction and that an end portion of the first groove portion 126g on the left side X2 side and an end portion of the second groove portion 220g on the left side X2 side are located at the same position in the Z-direction. Note that, in the example shown in FIG. 5A or the like, the first groove portion 126g and the second groove portion 220g are provided such that an opening portion of the first groove portion 126g on the upper side Z1 and an opening portion of the second groove portion 220g on the lower side Z2 overlap each other in the Z-direction when viewed in cross-sectional view but, for example, the first groove portion 126g and the second groove portion 220g may also be provided such that a portion of the opening portion of the first groove portion 126g on the upper side Z1 and a portion of the opening portion of the second groove portion 220g on the lower side Z2 overlap each other. For example, when viewed in cross-sectional view, the first groove portion 126g and the second groove portion 220g may also be provided such that, between an end portion on the right side X1 and an end portion on the left side X2 of the opening of the first groove portion 126g on the upper side Z1, an end portion on the right side X1 or an end portion on the left side X2 of the opening of the second groove portion 220g on the lower side Z2 is present.

In the electronic device 10 according to the example embodiment, due to such a configuration, the third resin portion 430 can be provided to, e.g., extend between the first groove portion 126g and the second groove portion 220g. Accordingly, in a case where the third resin portion 430 is provided in each of the first groove portion 126g and the second groove portion 220g, it is possible to further simplify a process of producing the third resin portion 430. Moreover, since the third resin portion 430 can be provided to extend between the first groove portion 126g and the second groove portion 220g, it is possible to provide a configuration capable of more effectively preventing the penetration of moisture into the interior of the electronic device 10 than in a case where, e.g., the third resin portion 430 is divided and separately provided in the first groove portion 126g and the second groove portion 220g.

Note that, in the electronic device 10 according to the example embodiment, at the bottom portion (bottom portion 126b shown in FIG. 5A) of the first groove portion 126g, a space layer 126bc (referred to also as a “first space layer” in the example embodiment) may also be provided. In the example embodiment, the space layer 126bc may also be, e.g., an air layer. In addition, in the example embodiment, as shown in FIG. 5A, e.g., the space layer 126bc may also be provided in a region between the bottom portion 126b and a portion on the lower side Z2 of the third resin portion 430.

In the example embodiment, in addition to or instead of the space layer 126bc provided at the bottom portion 126b of the first groove portion 126g, e.g., a space layer 126sc may also be provided in a side surface portion 126s of the first groove portion 126g. In the example embodiment, as shown in FIG. 5A, the first groove portion 126g has, e.g., the side surface portion 126s including a first side surface portion 126s1 provided on the right side X1 and a second side surface portion 126s2 provided on the left side X2, and the first side surface portion 126s1 and the second side surface portion 126s2 may also be provided respectively with a space layer 126sc1 and a space layer 126sc2 (referred to also as “second space layers” in the example embodiment). Similarly to the space layer 126bc, each of the space layer 126sc1 and the space layer 126sc2 may also be, e.g., an air layer.

For example, when moisture penetrates between the first groove portion 126g and the third resin portion 430, it is considered that, e.g., such moisture may penetrate into a portion closer to the interior of the electronic device 10 between the first groove portion 126g and the third resin portion 430 due to capillary action or the like. In the example embodiment, between the third resin portion 430 and the first groove portion 126g, the space layer 126bc, the space layer 126sc1, and the space layer 126sc2 are provided and, consequently, compared to a case where the space layer 126bc, the space layer 126sc1, and the space layer 126sc2 are not provided, it is possible to, e.g., delay or prevent the penetration of moisture, which has penetrated between the first groove portion 126g and the third resin portion 430, into the portion closer to the interior of the electronic device 10. Therefore, in the example embodiment, owing to the space layer 126bc, the space layer 126sc1, and the space layer 126sc2, it is possible to further prevent moisture, which has penetrated between the first groove portion 126g and the third resin portion 430, from penetrating into the interior of the electronic device 10.

In FIG. 5A, the description has been given by way of example of the case where the space layer 126bc, the space layer 126sc1, and the space layer 126sc2 are provided, but the configuration according to the example embodiment is not limited thereto. For example, even in a case where any one or two of the space layer 126bc, the space layer 126sc1, and the space layer 126sc2 are provided, in the same manner as described above, it is possible to prevent moisture, which has penetrated between the first groove portion 126g and the third resin portions 430, from penetrating into the interior of the electronic device 10.

In addition, not only between the first groove portion 126g and the third resin portion 430, but also between the second groove portion 220g and the third resin portion 430, the same space layers as the space layer 126bc, the space layer 126sc1, and the space layer 126sc2 may also be provided. In other words, in the side surface portions on the right side X1 and left side X2 of the second groove portion 220g and in the upper surface portion on the upper side Z1 of the second groove portion 220g also, the same space layers as the space layer 126bc, the space layer 126sc1, and the space layer 126sc2 may also be provided. In the case where the space layers are provided between the second groove portion 220g and the third resin portion 430 also, in the same manner as in the case where the space layers are provided between the first groove portion 126g and the third resin portion 430, it is possible to delay or prevent the penetration of moisture further into the interior of the electronic device 10.

While the description has been given by way of example of the case where, in the electronic device 10 according to the example embodiment described with reference to FIG. 5A and the like, rectangular groove portions as viewed in cross-sectional view are provided as the first groove portion 126g and the second groove portion 220g, the configuration of the electronic device 10 according to the example embodiment is not limited thereto. The shape of each of the first groove portion 126g and the second groove portion 220g may also be, e.g., a polygonal shape other than a rectangular shape as viewed in cross-sectional view or at least a portion of the polygonal shape. Alternatively, the shape of each of the first groove portion 126g and the second groove portion 220g may also be at least a portion of a circular shape or an ellipsoidal shape as viewed in cross-sectional view.

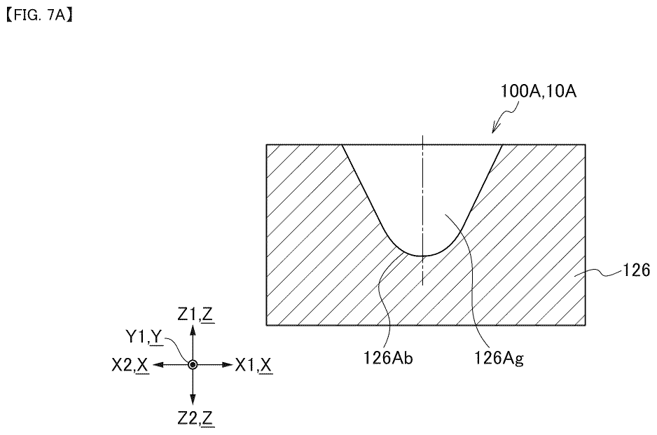

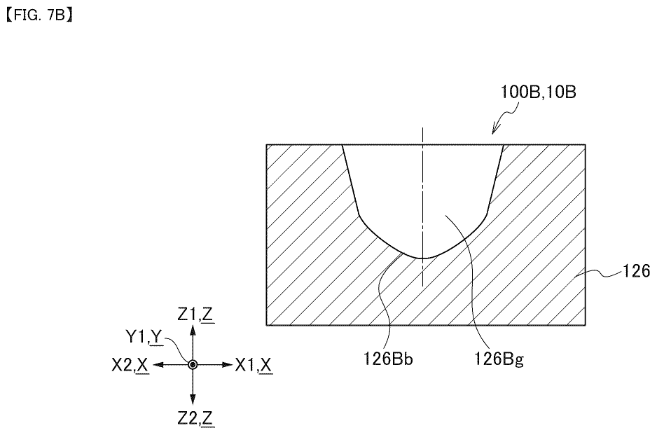

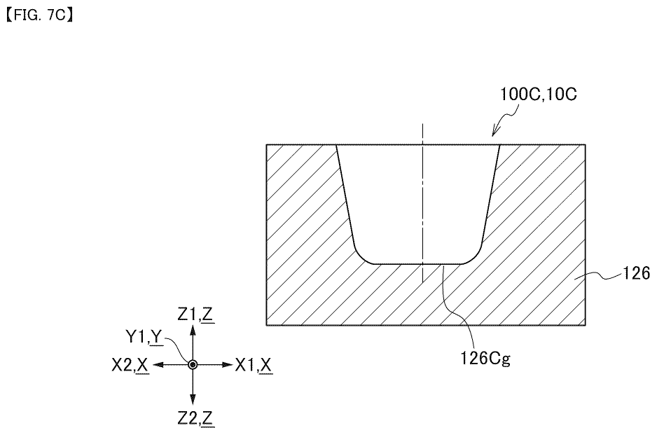

Referring to FIG. 7A to FIG. 7C, groove portions (first groove portions 126Ag (FIGS. 7A), 126Bg (FIG. 7B), and 126Cg (FIG. 7C) described later) each having a shape other than a rectangular shape as viewed in cross-sectional view will be described. FIG. 7A, FIG. 7B, and FIG. 7C are enlarged cross-sectional views of the vicinities of the first groove portions 126Ag, 126Bg, and 126Cg of respective base plates 100A, 100B, and 100C in electronic devices 10A, 10B, and 10C according to the example embodiment.

In the example embodiment, as shown in FIG. 7A, the shape of the first groove portion 126Ag is, e.g., a substantially triangular in cross section, and the bottom portion 126Ab may include a fillet having a radius R in cross section.

In the example embodiment, as shown in FIG. 7B, the shape of the first groove portions 126Bg is, e.g., a substantially pentagonal shape when viewed in cross-sectional view, and a corner portion of a pentagonal shape of a bottom portion 126Bb thereof may include a fillet having a radius R in cross section. Alternatively, in the example embodiment, as shown in FIG. 7C, the shape of the first groove portion 126Cg may be, e.g., a trapezoidal shape when viewed in cross-sectional view, and a corner portion of the trapezoidal shape may include a fillet having a radius R in cross section.

The shapes of the first groove portions 126Ag, 126Bg, and 126Cg respectively shown in FIG. 7A to FIG. 7C are illustrative, and the first groove portion 126g according to the example embodiment may also be formed to have straight lines and include a fillet having a radius R in cross section.

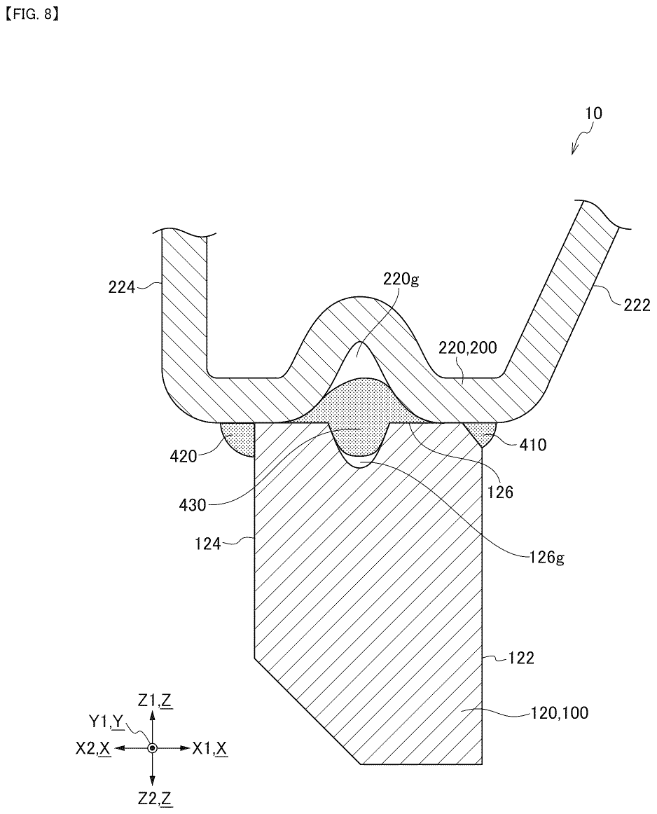

Referring to FIG. 8, another example of the shape of the groove portion 220g of the cover 200 will be described. Similarly to FIG. 4 or the like, FIG. 8 is an enlarged cross-sectional view of the vicinity of the joint portion between the cover contact portion 126 and the plate contact portion 220 in the electronic device 10A. As shown in FIG. 8, the second groove portion 220g of the cover 200 may also have, e.g., a substantially triangular shape when viewed in cross-sectional view. Alternatively, the second groove portion 220g of the cover 200 may also be provided by, e.g., bending the vicinity of the plate contact portion 220 of the cover 200 into a shape recessed on the upper side Z1 (upper side Z1 when the cover 200 is fixed to the base plate 100) when, e.g., the cover 200 is produced.

As described above, in the base plate 100 according to the example embodiment, as shown in FIG. 2A and FIG. 2B, the first groove portion 126g may also be provided along the entire circumference of the cover contact portion 126 and, similarly to the first groove portion 126g of the base plate 100, in the cover 200 also, the second groove portion 220g may also be provided along the entire circumference of the plate contact portion 220, as shown in FIG. 3B. Due to this configuration, it is possible to, e.g., prevent the occurrence of water leakage between the cover contact portion 126 and the plate contact portion 220 along the entire circumference of the electronic device 10, and therefore it is possible to effectively prevent the penetration of moisture into the interior of the electronic device 10.

Note that, in the example embodiment, both of the first groove portion 126g and the second groove portion 220g are provided along the entire circumferences of the cover contact portion 126 of the base plate 100 and the plate contact portion 220 of the cover 200, but the configuration according to the example embodiment is not limited thereto. For example, either of the first groove portion 126g and the second groove portion 220g may also be provided along the entire circumference of the cover contact portion 126 of the base plate 100 and the entire circumference of the plate contact portion 220 of the cover 200. Even in the case where either of the first groove portion 126g and the second groove portion 220g is provided along the entire circumference, it is possible to more effectively prevent the penetration of moisture into the interior of the electronic device 10.

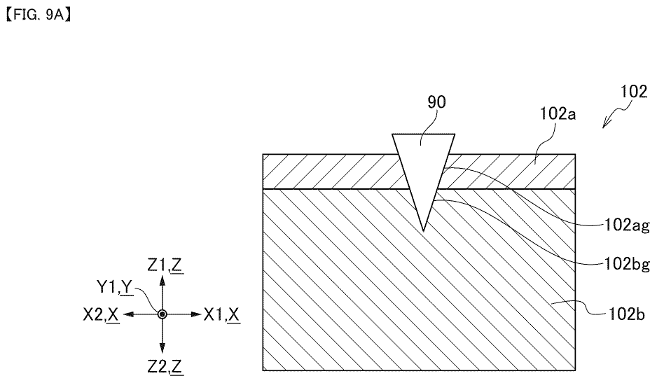

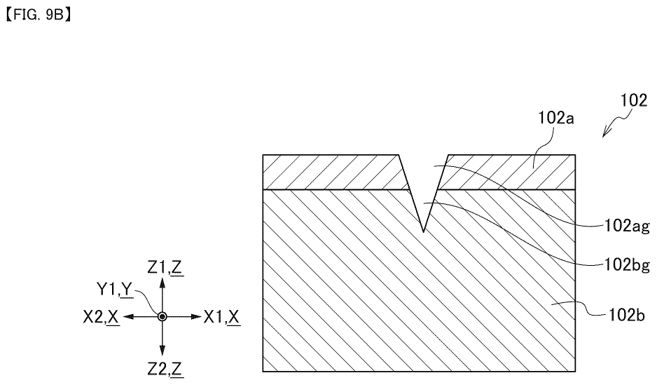

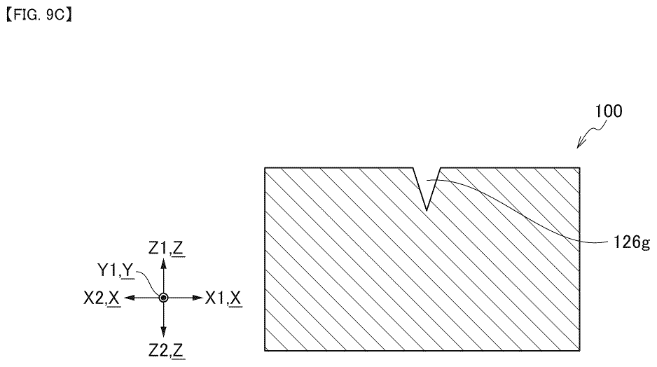

Referring to FIG. 9A to FIG. 9C, a method of forming the first groove portion 126g in the example embodiment will be described. FIG. 9A, FIG. 9B, and FIG. 9C are schematic cross-sectional views (cross-sectional views as viewed from the Y2-direction) for illustrating the method of forming the first groove portion 126g according to the example embodiment.

As shown in FIG. 9A, first, a base plate substrate 102 formed of a metal material by, e.g., aluminum die casting or the like is prepared. In a surface of the base plate substrate 102 on the upper side Z1, a groove portion 102ag and a groove portion 102bg are formed with a cutting tool 90 such as an end mill. Note that the base plate substrate 102 includes, e.g., a substrate portion 102b and a cutting stock portion 102a which is provided on the upper side Z1 of the substrate portion 102b. In addition, by using the cutting tool 90, the groove portions are formed in the base plate substrate 102 from the surface of the cutting stock portion 102a.

By using the cutting tool 90, as shown in FIG. 9B, e.g., the groove portion 102ag is formed in the cutting stock portion 102a, and the groove portion 102bg is formed on the lower side Z2 of the groove portion 102ag and on the upper side Z1 of the substrate portion 102b to be continued to the groove portion 120ag.

Subsequently, as shown in FIG. 9C, by removing the cutting stock portion 102a shown in FIG. 9B by etching or the like, the base plate 100 provided with the groove portion 126g described above is formed.

Note that the method described above with reference to FIG. 9A to FIG. 9C may also be used in a case where, e.g., the second groove portion 220g of the cover 200 is formed.

In the example embodiment, the first groove portion 126g and the second groove portion 220g are not limited to the method described above, and may also be formed by using, e.g., a mold.

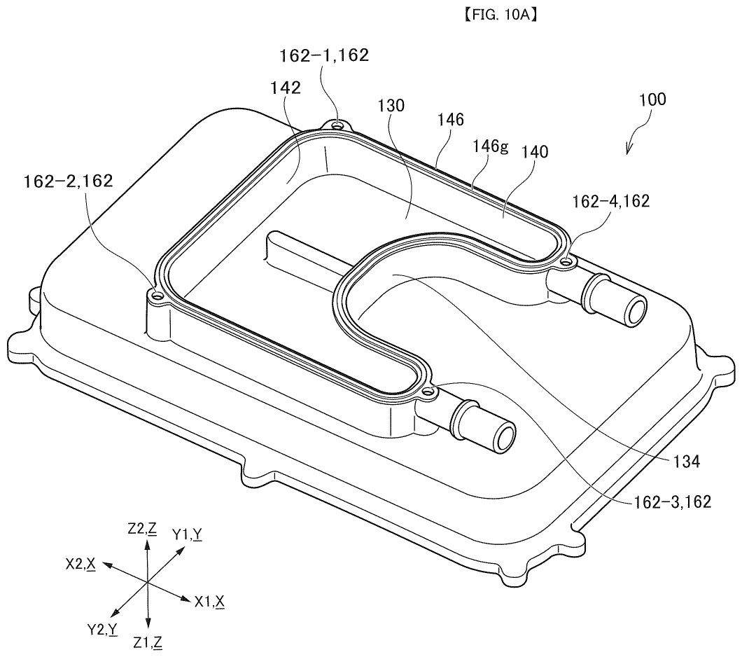

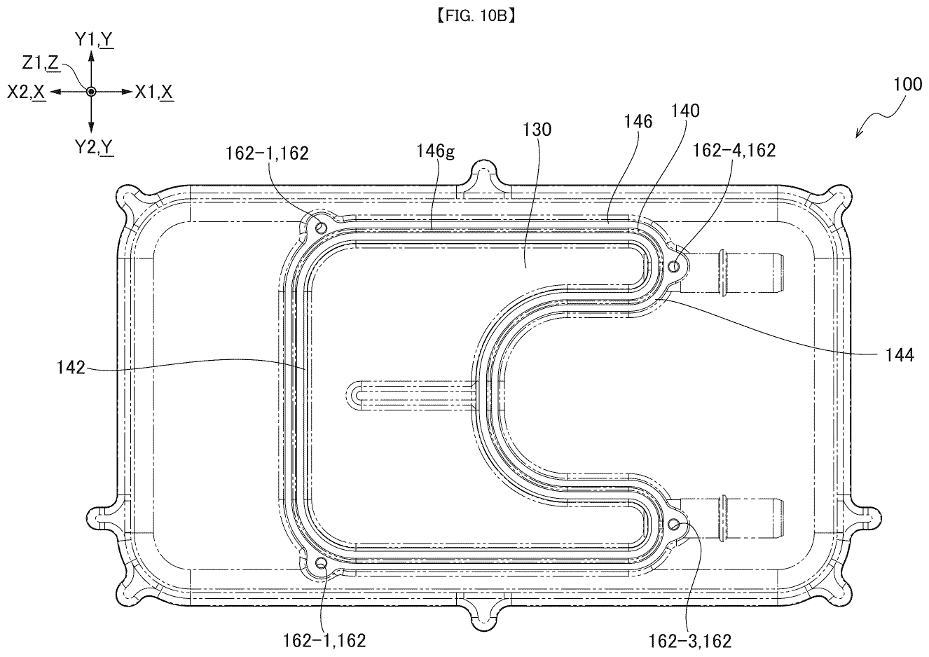

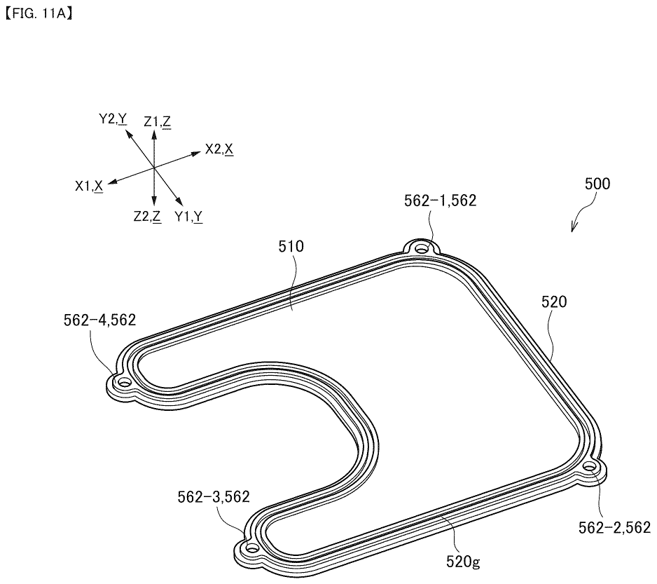

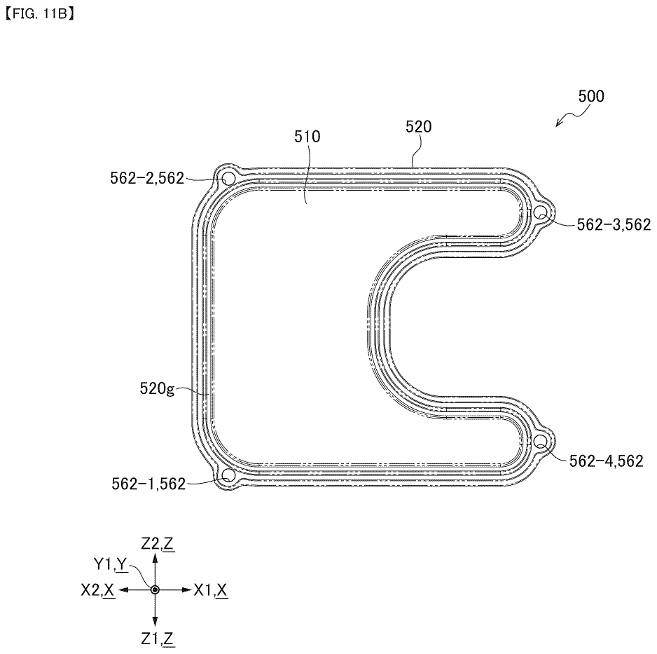

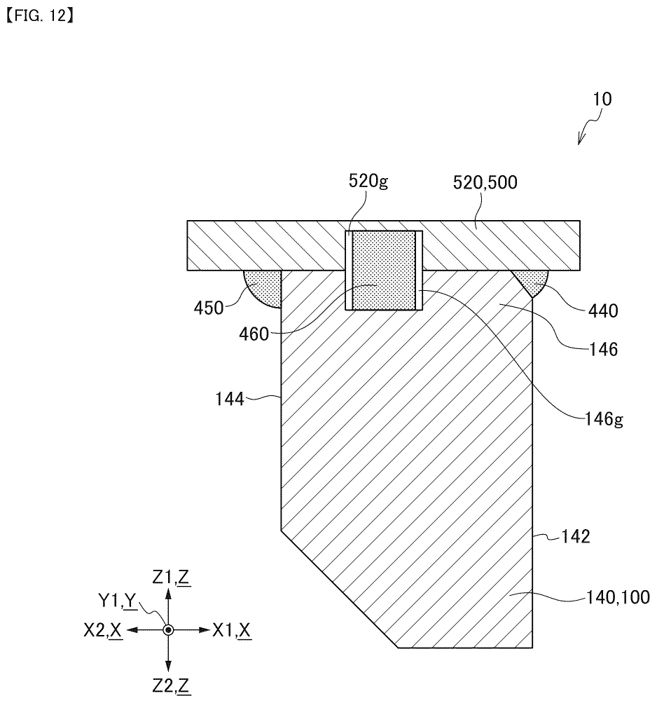

The electronic device 10 according to the example embodiment may also be configured such that, in addition to the configuration described heretofore, another cover (second cover) is further fixed, e.g., to the lower side Z2. Referring to FIG. 10A, FIG. 10B, FIG. 11A, FIG. 11B, and FIG. 12, this configuration will be described. FIG. 10A and FIG. 10B are a perspective view and a plan view of the lower side Z2 of the base plate 100, respectively. FIG. 11A and FIG. 11B are a perspective view and a plan view of the second cover 500, respectively. FIG. 12 is an enlarged cross-sectional view of a portion in which the second cover 500 is fixed to the base plate 100.

As shown in, e.g., FIG. 10A and FIG. 10B, the electronic device 10 according to the example embodiment further includes a second cover 500 fixed to a cover fixing surface 130, which is a surface of the base plate 100 opposite to (on the lower side Z2 of) the electronic substrate placement surface 110 thereof, and the base plate 100 may also include a second wall portion 140 protruding from the cover fixing surface 130. The second wall portion 140 has a third sidewall portion 142, a fourth sidewall portion 144 disposed outside of the third sidewall portion 142, and a second cover contact portion 146 which is provided between the third sidewall portion 142 and the fourth sidewall portions 144 to be in contact with the second cover 500, and has a third groove portion 146g provided in at least a portion thereof. Meanwhile, as shown in FIG. 11A and FIG. 11B, the second cover 500 has a plate facing surface 510 facing the cover fixing surface 130 of the base plate 100, and a second plate contact portion 520 which comes into contact with the second cover contact portion 146 of the base plate 100, and has a fourth groove portion 520g provided in at least a portion thereof.

As shown in FIG. 12, the electronic device 10 according to the example embodiment includes at least one of the fourth resin portion 440 which is fixed to the second plate contact portion 520 of the second cover 500 and to the third sidewall portion 142 and a fifth resin portion 450 which is fixed to the plate contact portion 520 of the second cover 500 and to the fourth sidewall portions 144, and a sixth resin portion 460 provided in at least one of the third groove portion 146g and the fourth groove portion 520g.

In the electronic device 10 according to the example embodiment, due to the configuration described above, for the same reason as described above with reference to, e.g., FIG. 5A, FIG. 5B, and the like, it is possible to prevent, even on the lower side Z2, the penetration of moisture from the outside of the electronic device 10 into the interior of the electronic device 10 through a space between the base plate 100 and the second cover 500.

Note that in the electronic device 10 according to the example embodiment, as shown in, e.g., FIG. 2A and FIG. 11A, the cover 200 which is fixed to the upper side Z1 of the base plate 100 and the second cover 500 which is fixed to the lower side Z2 of the base plate 100 may have different shapes when viewed in plan view. As also shown in FIG. 10A, FIG. 10B, FIG. 11A, and FIG. 11B, in the second cover contact portion 146 of the base plate and in the second plate contact portion 520 of the second cover 500, the third groove portion 146g and the fourth groove portion 520g may also be provided along the entire circumferences thereof.

As shown in FIG. 10A and FIG. 10B, the base plate 100 may also be provided with, e.g., a second cover fixing portion 162 for fixing the second cover 500 to the base plate 100. A plurality of the second cover fixing portions 162 may also be provided, and may include, e.g., second cover fixing portions 162-1, 162-2, 162-3, and 162-4. The second cover fixing portion 162 may also include, e.g., a screw hole into which a screw can be inserted.

In addition, as shown in FIG. 11A and FIG. 11B, the second cover 500 may also be provided with, e.g., a second plate fixing portion 562 for fixing the second cover 500 to the base plate 100. A plurality of the second plate fixing portions 562 may also be provided, and may include, e.g., second plate fixing portions 562-1, 562-2, 562-3, and 562-4. The second plate fixing portion 562 may also include, e.g., a screw hole into which a screw can be inserted.

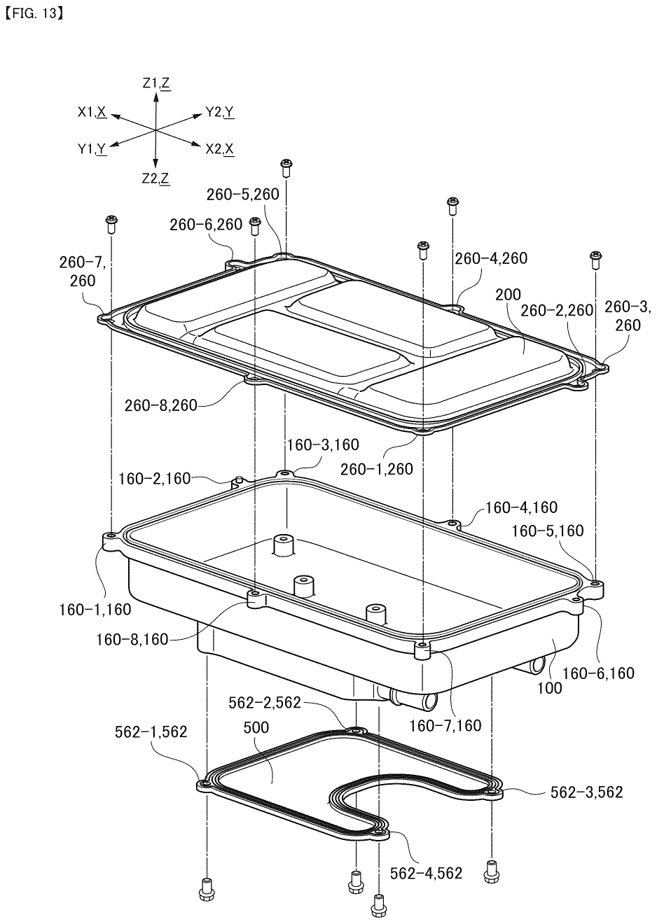

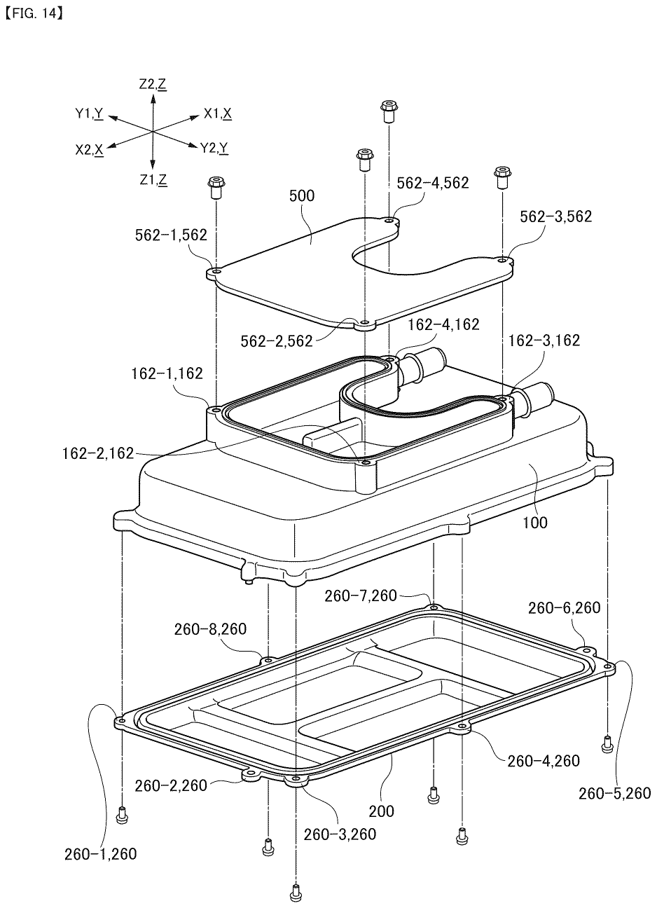

Referring to FIG. 13 and FIG. 14, a description will be given of a method of fixing the cover 200 and the second cover 500 to the base plate 100. In FIG. 13, from above the sheet surface in FIG. 13, the cover 200, the base plate 100, and the second cover 500 are shown in this order in a perspective view and, in FIG. 14, the second cover 500, the base plate 100, and the cover 200 are shown in this order in a perspective view.

As shown in FIG. 13 and FIG. 14, in a case where the cover 200 is fixed to the base plate 100, by respectively fixing, e.g., the plate fixing portions 260-1, 260-2, . . . , and 260-8 to the cover fixing portions 160-1, 160-2, . . . , and 160-8 of the base plate 100, the cover 200 is fixed to the base plate 100. Likewise, in a case where the second cover 500 is fixed to the base plate 100, by respectively fixing, e.g., the second plate fixing portions 562-1, 562-2, 562-3, and 560-4 to the second cover fixing portions 162-1, 162-2, 162-3, and 162-4 of the base plate 100, the second cover 500 is fixed to the base plate 100. In the example embodiment, when the cover 200 is fixed to the base plate 100 or when the second cover 500 is fixed to the base plate 100, the first resin portion 410, the second resin portion 420, and the third resin portion 430 or the fourth resin portion 440, the fifth resin portion 450, and the sixth resin portion 460 may also be provided.

The example embodiments described heretofore are intended to facilitate understanding of the present disclosure, and are not to be interpreted as limiting the present disclosure. Constituent elements of the example embodiments and arrangements, materials, conditions, shapes, sizes, and the like thereof are not limited to those shown by way of example, and can be changed as appropriate. In addition, components described in the different example embodiments can partially be substituted or combined.

1. An electronic device comprising:
an electronic substrate on which an electronic component is mounted;
a base plate on which the electronic substrate is placed;
a cover which is fixed to the base plate; and
a resin portion,
wherein the base plate includes:
a bottom surface;
a wall portion including a first sidewall portion and a second sidewall portion; and
a cover contact portion including a first groove portion,
wherein the first sidewall portion and the second sidewall portion extend from the bottom surface in a direction in which the electronic substrate is disposed,
wherein the cover contact portion is provided between the first sidewall portion and the second sidewall portion, and
wherein the cover includes:
a cover surface facing the electronic substrate; and
a plate contact portion that comes into contact with the cover contact portion, and has a second groove portion provided in at least a portion thereof, and
wherein the resin portion includes:
at least one of a first resin portion which is fixed to the plate contact portion and to the first sidewall portion and a second resin portion which is fixed to the plate contact portion and to the second sidewall portion; and
a third resin portion which is provided in at least one of the first groove portion and the second groove portion.

2. The electronic device according to claim 1,
wherein the second resin portion is included.

3. The electronic device according to claim 1, further comprising:
a fourth resin portion which is provided in at least a portion between the cover contact portion and the plate contact portion.

4. The electronic device according to claim 1,
wherein the first groove portion and the second groove portion are at least partially in communication with each other.

5. The electronic device according to claim 1,
wherein, between a bottom portion of the first groove portion or a bottom portion of the second groove portion and the third resin portion, a first space layer is provided.

6. The electronic device according to claim 1,
wherein, in the first groove portion or the second groove portion, between the cover contact portion and the third resin portion, a second space portion is provided.

7. The electronic device according to claim 1,
wherein the first groove portion or the second groove portion is at least a portion of a polygonal shape, a circular shape, or an ellipsoidal shape when viewed in cross-sectional view.

8. The electronic device according to claim 1,
wherein the first groove portion is provided along the entire circumference of the cover contact portion of the wall portion, and
wherein the second groove portion is provided along the entire circumference of the plate contact portion of the wall portion.

9. The electronic device according to claim 1, further comprising:
a second cover which is fixed to a cover fixing surface that is a surface of the base plate opposite to a surface thereof on which the electronic substrate is placed,
wherein the base plate includes:
a second wall portion protruding from the cover fixing surface and including:
a third sidewall portion;
a fourth sidewall portion disposed outside of the third sidewall portion; and
a second cover contact portion that is provided between the third sidewall portion and the fourth sidewall portion to come into contact with the second cover, and has a third groove portion provided in at least a portion thereof, and
wherein the second cover includes:
a plate facing surface facing the cover fixing surface; and
a second plate contact portion that comes into contact with the second cover contact portion, and has a fourth groove portion in at least a portion thereof,
the electronic device further comprising:
at least one of a fourth resin portion which is fixed to the second plate contact portion of the second cover and to the third sidewall portion and a fifth resin portion which is fixed to the second plate contact portion of the second cover and to the fourth sidewall portion; and
a sixth resin portion which is provided in at least one of the third groove portion and the fourth groove portion.
